(19) United States
(12) Patent Application Publication
(10) Pub. No.: US 2026/0060140 A1
(43) Pub. Date: Feb. 26, 2026

(54) SEMICONDUCTOR COMPONENT

(71) Applicant: Siemens Aktiengesellschaft, München (DE)

(72) Inventors: Walter Apfelbacher, Freihung (DE); Stefan Langen, Kastl (DE)

(21) Appl. No.: 18/997,532

(22) PCT Filed: May 15, 2023
(86) PCT No.: PCT/EP2023/062868

§ 371 Date: Jan. 22, 2025

(30) Foreign Application Priority Data
Aug. 3, 2022 (DE) 10 2022 208 031.9

(51) Int. Cl. H01L 23/00; H01L 25/07; H10D 80/20

(52) U.S. Cl. CPC H01L 24/48; H01L 24/49; H01L 25/072; H01L 24/32; H01L 2224/32258; H01L 2224/4814; H01L 2224/49175; H01L 2924/1301; H10D 80/20

(57) ABSTRACT

A semiconductor component has a circuit carrier with a first conductor layer, in which a first conductor path is formed. A first thyristor chip has, on its upper face, an anode contact and a gate contact and, on its lower face, a cathode contact placed for electrical connection on the first conductor path. A second thyristor chip has, on its upper face, a cathode contact and a gate contact and, on its lower face, an anode contact placed for electrical connection on the first conductor path. At least one electrically conductive connection element connects the anode contact of the first thyristor chip to the cathode contact of the second thyristor chip. The first conductor path thus establishes an electrical connection between the cathode contact of the first thyristor chip and the anode contact of the second thyristor chip.

The present invention relates to a semiconductor component having two thyristor chips; it furthermore relates to a power semiconductor module having a semiconductor component of this type.

In semiconductor switching devices, for example soft starters, an antiparallel circuit of two thyristors may be used as a semiconductor switch for switching an alternating current, see for example DE102016214419A1 (Siemens AG) Feb. 8, 2018. For this purpose, the cathode of a first thyristor chip must be connected to the anode of a second thyristor chip; furthermore, additional electrical connections must be produced in the antiparallel circuit.

It is known to implement these electrical connections of the thyristors by means of bonding wires, see for example WO2008/071134A1 (Siemens AG) Jun. 19, 2008 and DE102008031297A1 (Siemens AG) Jan. 14, 2010. In order to be able to deal with the current intensities arising in a power semiconductor module, multiple bonding wires running in parallel are sometimes required for each electrical connection, said bonding wires also having to be routed and bonded at an angled profile in many cases. This makes the production of an antiparallel circuit of two thyristors more difficult.

It is an object of the present invention to simplify the production of an antiparallel circuit of two thyristors. A further object of the present invention is to specify a thyristor circuit which is simpler to produce.

This object is achieved according to the invention by a semiconductor component having the features specified in claim 1. The semiconductor component comprises a circuit carrier which has a first conductor track in a first conductor layer. As an alternative, the circuit carrier may also be referred to as a “substrate”. The circuit carrier may be in the form of a so-called DCB (=direct copper bonding). A DCB is a sandwich consisting of two conductor layers, for example copper or aluminum layers, and an in-terposed insulating layer, for example a ceramic layer.

Compared to conventional printed circuit boards, for example epoxy printed circuit boards, a DCB of this type enables considerably higher temperatures for the components to be supported, in particular of the power semiconductors. In this case, the first conductor track may have been formed by a subdivision, for example by a structuring method such as photolithography in semiconductor technology, of the first conductor layer into line and connection structures which are electrically insulated from one another. The first conductor track of the first conductor layer is thus an electrically conductive surface which is arranged on an electrically insulating layer of a circuit carrier and which is electrically insulated from other conductor tracks of the first conductor layer. These conductor tracks are used as line structures and as contact surfaces for electronic components. All of the conductor tracks of a circuit carrier form a circuit layout on the insulating carrier layer.

The semiconductor component comprises a first thyristor chip which has an anode contact and a gate contact on its top side and a cathode contact on its bottom side; in this case, the first thyristor chip is placed by way of its cathode contact on the first conductor track in such a way that there is an electrical connection between the cathode contact and the first conductor track. The first conductor track has a first contact surface in planar form, against which the cathode contact of the first thyristor chip bears. In particular, the cathode contact is electrically connected to the first contact surface via a soldered connection, such that a low-resistance electrical transition with a low thermal conduction resistance at the same time is produced. The electrical connection, for example in the form of a soldered connection, additionally ensures that the first thyristor chip is mechanically fixed on the first conductor track of the first conductor layer.

The semiconductor component comprises a second thyristor chip which has a cathode contact and a gate contact on its top side and an anode contact on its bottom side; in this case, the second thyristor chip is placed by way of its anode contact on the first conductor track in such a way that there is an electrical connection between the anode contact and the first conductor track. The first conductor track has a second contact surface in flat form, against which the anode contact of the second thyristor chip bears. In particular, the anode contact is electrically connected to the second contact surface via a soldered connection, such that a low-resistance electrical transition with a low thermal conduction resistance at the same time is produced. The electrical connection, for example in the form of a soldered connection, additionally ensures that the second thyristor chip is mechanically fixed on the first conductor track of the first conductor layer.

The thyristor chips are thyristors in the form of micro-chips. In the present description, the thyristor chips are also simply referred to as thyristors. The individual thyristor chips may be plate-shaped or disk-shaped. They each have two main terminals, namely a cathode contact and an anode contact, and a control electrode terminal, namely a gate contact, wherein one of the main terminals and the control electrode terminal are located on the top side of the thyristor chip and the other main terminal is located on the bottom side of the thyristor chip.

A thyristor chip of this kind is, in particular, unpackaged. Essentially, a thyristor chip of this kind consists of the semiconductor chip itself, the so-called “die”. Contact-making surfaces for bonding, that is to say for electrically contacting, the electrodes of the thyristor chip are present on the die. The compact design enables a low-resistance connection of the thyristor chip to the conductor layer with a low heat transfer resistance at the same time for cooling the thyristor chip.

The semiconductor component has at least one electrically conductive connecting element, in particular a metal element, for example made of copper or aluminum, which electrically connects the anode contact of the first thyristor chip to the cathode contact of the second thyristor chip.

In addition, the first conductor track of the first conductor layer establishes an electrical connection between the cathode contact of the first thyristor chip and the anode contact of the second thyristor chip. Bonding wires, stamped parts or metal pieces produced in any desired manner can be used as the at least one electrically conductive connecting element; it is possible in principle to use any electrically conductive element which can be electrically conductively connected to the anode contact and the cathode contact. The arrangement of the electrically conductive connecting elements, in particular the route of the bonding wires, in the semiconductor component for producing the required electrical connections of the semiconductor component is referred to in a simplified manner as “bonding pattern”, even if the more general term “connecting element pattern”would be more correct at this juncture.

The invention is based on the knowledge that the bonding pattern and thus the production of an antiparallel circuit of two thyristors can be significantly simplified by using two different thyristor chips: a first thyristor chip with cathode at the bottom and a second thyristor chip with cathode at the top. In this case, the position of the anode contact and cathode contact of the first thyristor chip is interchanged with respect to the position of the second thyristor chip.

The invention makes it possible to implement the antiparallel circuit of the thyristors with a greatly simplified bonding pattern. The number of electrically conductive connecting elements which are to be arranged, in particular of the bonding wires which are to be run, is significantly reduced. The electrically conductive connecting elements need only be arranged on the top side of the chips. The route of the electrically conductive connecting elements is also straightened, for example. bonding with a straight route of the bonding wires is possible.

The invention enables simpler bonding wire placement and a reduction in the number of bonding wires, resulting in a reduction in the bonding costs. Installation space is also obtained as a result of the simplified bonding pattern and so larger semiconductors can be placed in a predefined installation space.

Advantageous embodiments and developments of the invention are specified in the dependent claims.

According to a preferred configuration of the invention, the semiconductor component has an input contact and an output contact. These two contacts make it possible to connect the semiconductor component into a circuit where the semiconductor component functions as a switch. In this case, the output contact is electrically connected to the anode contact of the second thyristor chip by the first conductor track of the first conductor layer. The semiconductor component also has at least one electrically conductive connecting element, for example at least one bonding wire, which electrically connects the input contact to the anode contact of the first thyristor chip. An advantage in this case is that the electrical connections required for the operation of the semiconductor component are produced by electrically conductive connecting elements, for example bonding wires, and by conductor tracks of the first conductor layer, which result in a simple bonding pattern.

According to a preferred configuration of the invention, the semiconductor component has a first control contact and a second control contact. The control contacts may be in the form of contact-making surfaces which are arranged on a carrier layer of the circuit carrier. They may be in the form of conductor tracks of the first conductor layer, for example copper or aluminum fields arranged on a carrier layer of the circuit carrier, which are electrically insulated from other conductor tracks of the first conductor layer. In this case, the semiconductor component also has at least one actuation wire which electrically connects the first control contact to the gate contact of the first thyristor chip. And the semiconductor component has at least one actuation wire which electrically connects the second control contact to the gate contact of the second thyristor chip. An advantage in this case is that the electrical connections required for the operation of the semiconductor component are produced by electrically conductive connecting elements, for example bonding wires, which result in a simple bonding pattern.

According to a preferred configuration of the invention, the semiconductor component has a third control contact. The control contact may be in the form of a contact-making surface which is arranged on a carrier layer of the circuit carrier. It may be in the form of a conductor track of the first conductor layer, for example a copper or aluminum field arranged on a carrier layer of the circuit carrier, which is electrically insulated from other conductor tracks of the first conductor layer. And the semiconductor component has at least one auxiliary wire which electrically connects the third control contact to the cathode contact of the second thyristor chip. An advantage in this case is that the electrical connections required for the operation of the semiconductor component are produced by bonding wires, which result in a simple bonding pattern.

According to a preferred configuration of the invention, the semiconductor component has a fourth control contact which is electrically connected to the cathode contact of the first thyristor chip by the first conductor track of the first conductor layer. The fourth control contact may be in the form of a contact-making surface of the first conductor track. An advantage in this case is that electrical connections required for the operation of the semiconductor component are produced by conductor tracks of the first conductor layer, which result in a simple bonding pattern.

Another preferred configuration of the invention is a power module, short for: power semiconductor module, having a semiconductor component according to one of the configurations described above. A power semiconductor module is an electrical apparatus which, with the aid of semiconductor components, can convert electrical energy as efficiently as possible into the form required by various applications and can reliably control the power flow via suitable circuits. In addition to a semiconductor component according to the invention, the power module according to the invention has a heat sink, a housing and a potting compound, for example a plastic. In this case, the circuit carrier of the semiconductor component has, in addition to the first conductor layer arranged on the top side of the circuit carrier, a second conductor layer arranged on the bottom side of the circuit carrier, and a central layer which electrically insulates the two aforementioned conductor layers from one another.

The circuit carrier may be a DCB; in this case, the two conductor layers may be copper or aluminum layers and the central layer may be a ceramic layer. However, the possible configurations of a DCB are sufficiently known to those skilled in the art and need not be explained further at this juncture. The semiconductor component is arranged on the heat sink and is housed in the housing which is filled with the potting compound. Power semiconductor modules are installed in housings for isolation from environmental influences. These housings protect the module from mechanical destruction, moisture and other harmful external effects. The housing is usually encapsulated with a filling compound which serves as an electrical insulation layer and simultaneously as a mechanical holder. This results in a plastic body in which the electrical and/or electronic parts and components are completely embedded and from which only the electrical supply and discharge lines of the power module protrude.

According to a preferred configuration of the power module, connecting layers are arranged in each case between the thyristor chips and the first conductor layer and between the heat sink and the second conductor layer. Said connecting layers may be layers of solder or other electrically conductive materials. The connecting layers establish mechanical fixing and an electrical and thermal connection between the connected components.

According to a preferred configuration of the power module, the input contact and the output contact of the semiconductor component are each electrically connected through the potting compound to a first and second contacting apparatus which are arranged outside the housing. The power module thus has a plastic body in which the electrical and/or electronic parts and components are completely embedded and from which only the electrical supply and discharge lines of the power module protrude.

The invention is explained below with reference to the accompanying drawing. In the drawing, schematically and not to scale in each case,

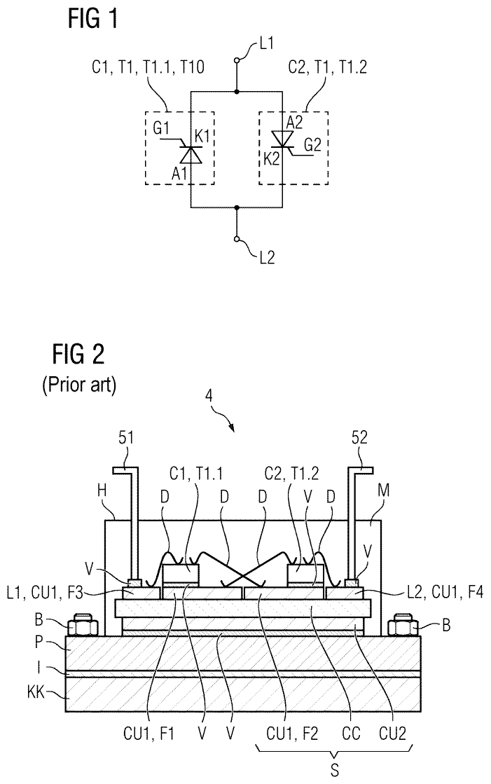

FIG. 1 shows a circuit diagram of a pair of thyristors;

FIG. 2 shows a section through a conventional power module;

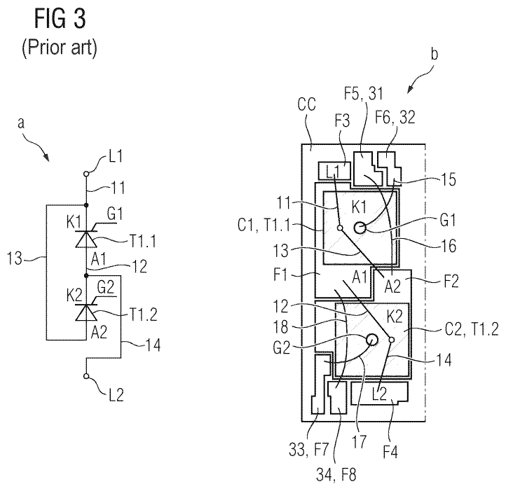

FIG. 3 shows a circuit diagram and a bonding pattern of a conventional pair of thyristors;

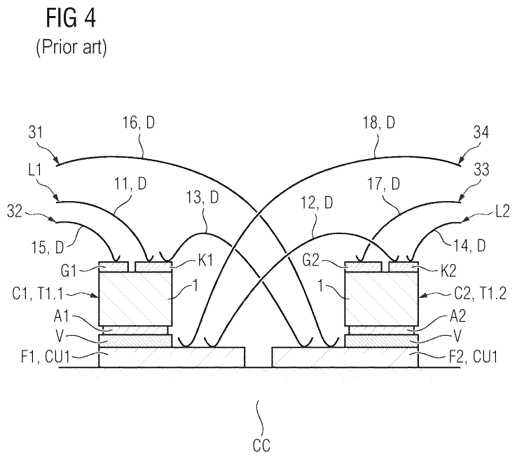

FIG. 4 shows a section of a conventionally interconnected pair of thyristors;

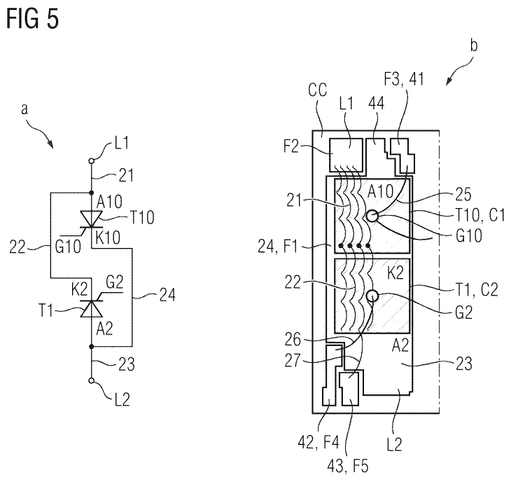

FIG. 5 shows a circuit diagram and a bonding pattern of a pair of thyristors according to the invention;

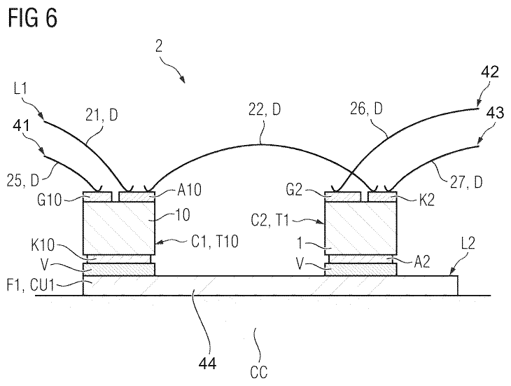

FIG. 6 shows a section of a pair of thyristors interconnected in accordance with the invention;

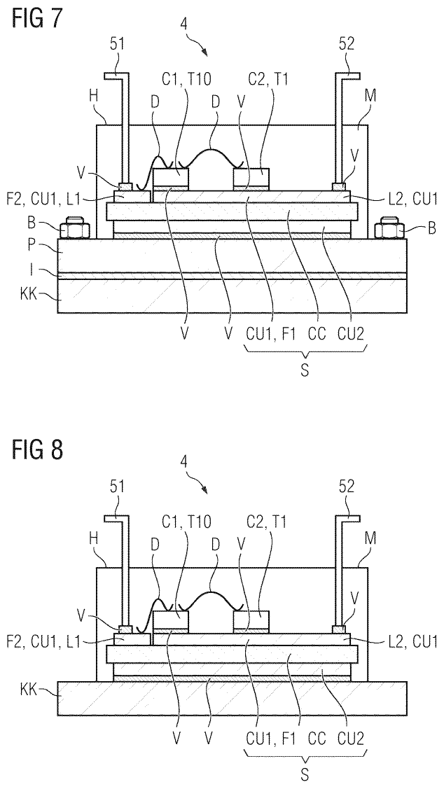

FIG. 7 shows a section through a power module according to the invention according to a first configuration; and

FIG. 8 shows a section through a power module according to the invention according to a further configuration.

FIG. 1 shows a schematic circuit diagram of a component which has a pair of thyristors T1.1, T1.2 which are connected in antiparallel and which can be connected to the two poles of an AC voltage source via contact pieces L1, L2 of the component. In this case, the thyristors T1.1, T1.2 may each be in the form of a semiconductor chip C1, C2. The thyristors T1.1, T1.2 each have an anode A1, A2, a cathode K1, K2 and a gate electrode G1, G2. A controller can be used to switch on both thyristors T1.1, T1.2 by applying a current to each of the gate electrodes G1, G2, that is to say said thyristors can be changed from an initial off state to an on state. Switching on a thyristor by applying said gate current is referred to as “ignition”. Once ignited, the thyristors remain on even without an applied gate current until the current flowing through the conductive thyristor falls below a minimum value, the so-called holding current.

In conventional antiparallel-connected thyristor pairs T1.1, T1.2, two thyristors of the same type T1 with the same construction are used: in the case of both thyristor chips T1.1, T1.2, the cathode K1, K2 is at the same position, for example at the top of the chip. In contrast, in an antiparallel-connected thyristor pair according to the invention, two thyristors of different types T10, T1 of different construction are used: a first thyristor chip C1, T10 has its cathode K1 at the bottom and a second thyristor chip C2, T1 has its cathode K2 at the top, that is to say in a manner mirrored with respect to the first thyristor chip C1, T10.

FIG. 2 shows a section of a conventional power semiconductor module 4 in which a conventionally antiparallel-connected thyristor pair T1.1, T1.2 is installed. The power semiconductor module has a typical hybrid power electronics construction having a plurality of power semiconductor components C1, C2 which are combined on a substrate/circuit carrier and are interconnected with one another. The populating of the power semiconductor module 4 comprises at least one semiconductor component C1, C2 which has an anti-parallel-connected thyristor pair T1.1, T1.2. The power semiconductor module 4 may have yet further semiconductor components, such as, for example, GTOs (=gate turn-off thyristors), MCTs (=MOS-controlled thyristors), power diodes, IGBTs (=insulated-gate bipolar transistors) or MOSFETS (=metal-oxide-semiconductor field-effect transistors). However, a module 4 may also include other wiring components, for example passive components and sensors. The semiconductor components of a conventional power semiconductor module 4 are commercially available components and are therefore not described in any more detail below.

The power semiconductor module 4 contains a base plate P. In the example illustrated, the base plate P is connected by means of a heat-conducting layer I to a heat sink KK, which may have cooling ribs in order to dissipate the heat generated by the semiconductor elements. The illustration of cooling ribs on the heat sink KK in FIG. 2 has been omitted for reasons of simplification. Another advantageous embodiment would be, for example, a liquid cooler. The heat-conducting layer I may consist of a TIM (=thermal interface material) which improves the thermal coupling between the base plate P and the heat sink KK. The base plate P is secured to the heat sink KK by a fastening apparatus B; in this case, as close a contact as possible between the base plate P and the heat sink KK supports the dissipation of heat from the semiconductor components C1, C2.

The base plate P is preferably produced from a material with good thermal conductivity, for example from a metal such as aluminum or copper or a metal/matrix composite such as aluminum-silicon carbide (AlSiC) or copper-silicon carbide (CuSiC). In this case, a base plate P composed of a metal-ceramic composite (AlSiC, CuSiC) can be combined well with cooling structures KK composed of the same composite or composed of the associated metal (Al, Cu).

In the construction shown, the power semiconductor components C1, C2 are constructed on a circuit carrier S. The circuit carrier S forms an electrical insulation between the semiconductor components C1, C2 and the base plate P and additionally has a good thermal conductivity in order to dissipate the heat from the semiconductor components C1, C2 to the base plate P. In this case, the circuit carrier S may have a ceramic layer CC, wherein aluminum nitride (AlN), aluminum oxide (Al2O3), beryllium oxide (BeO), silicon carbide (SiC) or silicon nitride (SiN) are preferred materials. Owing to the high thermal conductivity and thermal coefficients of expansion, preference is given to using ceramic circuit carriers S, so-called DCB substrates, which consist of a ceramic insulator CC such as aluminum oxide or aluminum nitride, on both sides of which in each case a thin layer of pure copper, specifically a first conductor layer CU1, is applied to a top side of the ceramic layer CC and a second conductor layer CU2 is applied to a bottom side of the ceramic layer CC, as illustrated in FIG. 2. The circuit carrier S is connected to the base plate P via a solder layer V.

On its top side facing the semiconductor components C1, C2, the circuit carrier S has metallized conductor tracks F1, F2, F3, F4 which are structured according to circuit requirements: in the present example, the conductor tracks F1 to F4 comprise an input contact L1, an output contact L2, a first conductor track F1 and a second conductor track F2. The conductor tracks F1 to F4 were formed by a subdivision of the first conductor layer CU1, which was arranged on the top side of the ceramic layer CC.

The electronic semiconductor components C1, C2 are mechanically and electrically connected to the conductor tracks F1 to F4; these electrical connections may be produced by solder layers V. Instead of the solder layers V between the semiconductor components C1, C2 and the circuit carrier S, another cohesive connection or securing which ensures good electrical and thermal contact is also possible, for example via an intermediate layer in the form of a metal plate. Electrical connections between the conductor tracks F1 to F4 and the semiconductor components C1, C2 are produced by bonding wires D.

The power semiconductor module 4 furthermore comprises a housing H which is closed off by the base plate P and thus forms a housing interior. Plastic housings are customary. In addition to being made of plastic, the housing H may also be made of another dielectric, in particular a ceramic. Ceramics are inexpensive and resistant and have good thermal conductivity for electrical insulators. This thermal conductivity is important in order to dissipate the heat arising.

For mutual electrical insulation of the components of the power semiconductor module 4 and for sealing off the circuit construction from the external atmosphere, the housing H is at least partially encapsulated with a potting compound M in the direction of the base plate P. Typically, the housing volume is filled with potting compound M to such an extent that it uniformly surrounds the semiconductor components C1, C2 and the customary standard specifications are met. The terminals 51, 52 of the power semiconductor module 4 are led out of the encapsulated housing H at suitable locations via the contacts L1, L2 of the circuit carrier S and solder layers V in order to provide external terminals of the power semiconductor module 4.

FIG. 3 shows a conventional semiconductor component with a thyristor pair connected in antiparallel in a circuit diagram in part a and a bonding pattern in part b. The circuit diagram (FIG. 3a) shows two thyristors T1.1, T1.2 which are of identical design and are interconnected with one another in antiparallel. In both thyristor chips T1.1, T1.2, the cathode K1, K2 is at the same position on the top side of the chip. In both thyristor chips T1.1, T1.2, the gate Gl, G2 is at the same position on the top side of the chip. In both thyristor chips T1.1, T1. 2, the anode A1, A2 is at the same position on the bottom side of the chip.

The interconnection of the two thyristor chips T1. 1, T1. 2 is as follows: the input contact L1 of the circuit is connected to the cathode Kl of the first transistor chip T1.1 by means of a first bonding connection 11. The anode A1 of the first transistor chip T1.1 is connected to the cathode K2 of the second transistor chip T1.2 by means of a second bonding connection 12. The cathode K1 of the first transistor chip T1.1 is connected to the anode A2 of the second transistor chip T1.2 by means of a third bonding connection 13. The cathode K2 of the second transistor chip T1.2 is connected to the output contact L2 by means of a fourth bonding connection 14.

The bonding pattern (FIG. 3b) shows a plan view of a conventionally interconnected thyristor pair. Eight conductor tracks which are electrically insulated from one another are formed from the copper layer, which is arranged as the first conductor layer CU1 on the ceramic layer CC of the circuit carrier, by a structuring method: the input contact L1 of the semiconductor component forms a third conductor track F3. The first transistor chip C1, T1.1 is arranged by way of its anode contact A1 on a first conductor track F1. The second transistor chip C2, T1.2 is arranged by way of its anode contact A2 on a second conductor track F2. And the output contact L2 of the semiconductor component forms a fourth conductor track F4. Furthermore, a first control contact 31 forms a fifth conductor track F5, a second control contact 32 forms a sixth conductor track F6, a third control contact 33 forms a seventh conductor track F7, and a fourth control contact 34 forms an eighth conductor track F8.

The interconnection of the two thyristor chips T1.1, T1.2 is as follows: The third conductor track F3, that is to say the input contact L1 of the circuit, is connected to the cathode K1 of the first transistor chip T1.1 by means of a first bonding connection 11. The first conductor track Fl, to which the anode A1 of the first transistor chip T1.1 is soldered, is connected to the cathode K2 of the second transistor chip T1.2 by means of a second bonding connection 12. The cathode Kl of the first transistor chip T1.1 is connected to the second conductor track F2, to which the anode A2 of the second transistor chip T1.2 is soldered, by means of a third bonding connection 13. The cathode K2 of the second transistor chip T1.2 is connected to the fourth conductor track F4, that is to say the output contact L2 of the circuit, by means of a fourth bonding connection 14.

The fifth conductor track F5, which forms a first control contact 31 (auxiliary cathode) of the circuit, is supplied with the potential of the cathode K1 of the first transis-tor T1.1 by means of a first auxiliary wire 16, wherein the first auxiliary wire 16 is connected by a first end to the anode A2 of the second transistor T1.2 which is at the potential of the cathode K1 of the first transistor T1.1. The first auxiliary wire 16 is connected by another end to the first control contact 31, from which an electrical connection to a controller for actuating the first thyristor T1. 1 can be established. The first control contact 31, via which energy from the main circuit can be made available to the controller, is used for actuating the gate Gl of the first transistor chip T1.1.

A first actuation wire 15 runs from the sixth conductor track F6, which forms a second control contact 32 of the circuit, to the gate G1 of the first thyristor T1.1.

A second actuation wire 17 runs from the seventh conductor track F7, which forms a third control contact 33 of the circuit, to the gate G2 of the second thyristor T1.2.

The eighth conductor track F8, which forms a fourth control contact 34 (auxiliary cathode) of the circuit, is supplied with the potential of the cathode K2 of the second transistor T1.2 by means of a second auxiliary wire 18, wherein the second auxiliary wire 18 is connected by a first end to the anode A1 of the first transistor T1.1 which is at the potential of the cathode K2 of the second transistor T1. 2. The second auxiliary wire 18 is connected by another end to the fourth control contact 34, from which an electrical connection to a controller for actuating the second thyristor T1.2 can be established. The fourth control contact 34, via which energy from the main circuit can be made available to the controller, is used for actuating the gate G2 of the second transistor chip T1.2.

In order to be able to deal with the current intensities arising in the power semiconductor component C1, C2, multiple bonding wires running in parallel are required for each electrical connection 11, 12, 13, 14, said bonding wires also having to be routed and bonded in an angled profile. This makes the production of an antiparallel circuit of two thyristors with a bonding pattern according to FIG. 3b by means of wire bonding more difficult.

FIG. 4 shows a section of two conventionally interconnected thyristors T1, T2 in accordance with the switching/bonding pattern of FIG. 3. The two thyristor chips C1, C2 have the Same structure, that is to say in each case one anode contact A1, A2 arranged on the bottom side of the chip, in each case one cathode contact K1, K2 arranged on the top side of the chip, and in each case one gate contact G1, G2 arranged on the top side of the chip. Between the contacts on the top side and the bottom side there is a semiconductor layer structure 1, which is likewise identical in the case of both thyristor chips C1, C2.

The first thyristor chip C1, T1.1 is arranged on the first conductor track F1. In this case, the anode contact A1 arranged on the bottom side of the first thyristor chip C1, T1.1 is electrically and mechanically connected to the first conductor track F1 by means of a solder layer V. The cathode contact K1 and the gate contact G1 are arranged on the top side of the first thyristor chip C1, T1.1.

The second thyristor chip C2, T1.2 is arranged on the second conductor track F2. In this case, the anode contact A2 arranged on the bottom side of the second thyristor chip C2, T1.2 is electrically and mechanically connected to the second conductor track F2 by means of a solder layer V. The cathode contact K2 and the gate contact G2 are arranged on the top side of the second thyristor chip C2, T1.2.

With regard to the electrical interconnection of the two thyristor chips C1, C2 by bonding wires D, reference is made to the description relating to FIG. 3b.

FIG. 5 shows an inventive semiconductor component with a thyristor pair C1, C2 connected in antiparallel in a circuit diagram in part a and a bonding pattern in part b. The circuit diagram (FIG. 5a) shows two thyristors T10, T1 which are of different design and are interconnected with one another in antiparallel. The cathode K10 of the first thyristor chip T10 is on the bottom side of the chip, whereas the cathode K2 of the second thyristor chip T1 is on the top side of the chip. The anode A10 of the first thyristor chip T10 is on the top side of the chip, whereas the anode A2 of the second thyristor chip T1 is on the bottom side of the chip. The gate G10 of the first thyristor chip T10 as well as the gate G2 of the second thyristor chip T1 are on the top side of the respective chip.

The interconnection of the two thyristor chips T10, T1 is as follows: the input contact L1 of the circuit is connected to the anode A10 of the first transistor chip T10 by means of a first bonding connection 21. The anode A10 of the first transistor chip T10 is connected to the cathode K2 of the second transistor chip T1 by means of a second bonding connection 22. The anode A2 of the second transistor chip T1 is connected to the output contact L2 by means of a third bonding connection 23. The cathode K10 of the first transistor chip T10 is connected to the anode A2 of the second transistor chip T1 by means of a connection 24 which is not a bonding wire connection. Instead of using bonding wires, the electrical connections 21, 22, 23 may also be made using other connecting elements.

The bonding pattern (FIG. 5b) shows a plan view of a thyristor pair C1, C2 interconnected according to the invention. Six conductor tracks electrically insulated from one another have been formed from the copper layer, which is arranged as a first conductor layer CU1 on the ceramic layer CC of the circuit carrier, by a known structuring method: Both transistor chips C1, C2 are arranged on a first conductor track F1: the first transistor chip C1, T10 is arranged by way of its cathode contact K10 on the first conductor track F1, whereas the second transistor chip C2, T1 is arranged by way of its anode contact A2 on the first conductor track F1. A fourth control contact 44, like the output contact L2 of the semiconductor component, are also placed on the first conductor track F1. The input contact L1 of the semiconductor component forms a second conductor track F2. Furthermore, a first control contact 41 forms a third conductor track F3, a second control contact 42 forms a fourth conductor track F4, and a third control contact 43 forms a fifth conductor track F5.

The interconnection of the two thyristor chips T10, T1 is as follows: The second conductor track F2, that is to say the input contact L1 of the circuit, is connected to the anode A10 of the first transistor chip T10 by means of a first bonding connection 21. The first conductor track F1, which is formed as a copper layer and onto which the cathode K10 of the first transistor chip T10 and the anode K2 of the second transistor chip T1 are soldered, connects the cathode K10 of the first transistor chip T10 to the anode K2 of the second transistor chip T1. The anode A10 of the first transistor chip T10 is connected to the cathode K2 of the second transistor chip T1 by means of a second bonding connection 22. The anode A2 of the second transistor chip T1 is connected to the output contact L2 of the circuit by the first conductor track F1. Instead of using bonding wires, the electrical connections 21, 22 may also be made using other connecting elements.

An electrical connection to a controller for actuating the first thyristor T10 can be established from the fourth control contact 44, which is in the form of a projection of the first conductor track F1 and is at the potential of the cathode K10 of the first transistor T10. The fourth control contact 44, via which energy from the main circuit can be made available to the controller, is used for actuating the gate G10 of the first transistor chip T10.

A first actuation wire 25 runs from the third conductor track F3, which forms a first control contact 41 of the circuit, to the gate G10 of the first thyristor T10.

A second actuation wire 26 runs from the fourth conductor track F4, which forms a second control contact 42 of the circuit, to the gate G2 of the second thyristor T1.

The fifth conductor track F5, which forms a third control contact 43 of the circuit, is supplied with the potential of the cathode K2 of the second transistor T1 by means of an auxiliary wire 27, wherein the auxiliary wire 27 is connected by a first end to the cathode K2 of the second transistor T1. The auxiliary wire 27 is connected by another end to the third control contact 43, from which an electrical connection to a controller for actuating the second thyristor T1 can be established. The third control contact 43, via which energy from the main circuit can be made available to the controller, is used for actuating the gate G2 of the second transistor chip T1.

In order to be able to deal with the current intensities arising in the power semiconductor component C1, C2, multiple bonding wires running in parallel are required for each electrical connection 21, 22. However, the configuration of the thyristors and the antiparallel circuit according to the invention results in a greatly simplified bonding pattern in which the number of wires to be run overall is significantly reduced and only has to be bonded on the top side of the chips. In addition, the invention allows a straight route of the bonding wires. This makes the production of an antiparallel circuit of two thyristors with a bonding pattern according to FIG. 5b by means of wire bonding significantly easier. The establishment of the electrical connections by connecting elements other than bonding wires is also facilitated by the arrangement of the thyristor chips according to the invention: the connecting elements may run, inter alia, in a straight line.

As an alternative to the embodiment shown in FIG. 5b, the output contact L2 of the semiconductor component may also be in the form of a conductor track which is separated from the first conductor track F1 and which is electrically connected to the first conductor track F1 by an electrical connecting element, for example one or more bonding wires. This alternative embodiment is advantageous, for example, when the first conductor track F1 and the conductor track of the output contact L2 separated therefrom are intended to lie at different height levels relative to the plane of the ceramic layer CC.

FIG. 6 shows a section of two thyristors T10, T1 interconnected with one another according to the invention in accordance with the switching/bonding pattern of FIG. 5. The two thyristor chips C1, C2 have a different structure: The cathode K10 of the first thyristor chip C1, T10 is on the bottom side of the chip, whereas the cathode K2 of the second thyristor chip C2, T1 is on the top side of the chip. The anode A10 of the first thyristor chip C1, T10 is on the top side of the chip, whereas the anode A2 of the second thyristor chip C2, T1 is on the bottom side of the chip.

The gate G10 of the first thyristor chip C1, T10 and the gate G2 of the second thyristor chip C2, T1 are both on the top side of the respective chip. Between the contacts on the top side and the bottom side there is a respective semiconductor layer structure 1, 10, which is likewise different in both thyristor chips C1, C2.

The first thyristor chip C1, T10 is arranged on the first conductor track F1. In this case, the cathode contact K10 arranged on the bottom side of the first thyristor chip Cl, T10 is electrically and mechanically connected to the first conductor track F1 by means of a solder layer V. The anode contact A10 and the gate contact G10 are arranged on the top side of the first thyristor chip C1, T10.

The second thyristor chip C2, T1 is also arranged on the first conductor track F1. In this case, the anode contact A2 arranged on the bottom side of the second thyristor chip C2, T1 is electrically and mechanically connected to the first conductor track F1 by means of a solder layer V. The cathode contact K2 and the gate contact G2 are arranged on the top side of the second thyristor chip C2, T1.

With regard to the electrical interconnection of the two thyristor chips C1, C2 by bonding wires D, reference is made to the description relating to FIG. 5b.

FIG. 7 shows a section of a power module 4 according to the invention in accordance with a first configuration, in which a thyristor pair T10, T1 connected in antiparallel in accordance with the invention is installed.

The power semiconductor module has a typical hybrid power electronics construction having a plurality of power semiconductor components C1, C2 which are combined on a substrate/circuit carrier and are interconnected with one another. The populating of the power semiconductor module 4 comprises at least one semiconductor component C1, C2 which has an antiparallel-connected thyristor pair T10, T1.2. The power semiconductor module 4 may include yet further semiconductor components, such as GTOs, MCTs, power diodes, IG-5 BTs, or MOSFETS, for example. However, a module 4 may also include other wiring components, for example passive components and sensors. The semiconductor components of a conventional power semiconductor module 4 are commercially available components and are therefore not described in any more detail below.

The power semiconductor module 4 contains a base plate P. In the example illustrated, the base plate P is connected by means of a heat-conducting layer I to a heat sink KK, which may have cooling ribs in order to dissipate the heat generated by the semiconductor elements. The illustration of cooling ribs on the heat sink KK in FIG. 7 has been omitted for reasons of simplification. Another advantageous embodiment would be, for example, a liquid cooler. The heat-conducting layer I may consist of a TIM which improves the thermal coupling between the base plate P and the heat sink KK. The base plate P is secured to the heat sink KK by a fastening apparatus B; in this case, as close a contact as possible between the base plate P and the heat sink KK supports the dissipation of heat from the semiconductor components C1, C2.

The base plate P is preferably produced from a material with good thermal conductivity, for example from a metal such as aluminum or copper or a metal/matrix composite such as aluminum-silicon carbide (AlSiC) or copper-silicon carbide (CuSiC). In this case, a base plate P composed of a metal-ceramic composite (AlSic, CuSiC) can be combined well with cooling structures KK composed of the same composite or composed of the associated metal (Al, Cu).

In the construction shown, the power semiconductor components C1, C2 are constructed on a circuit carrier S. The circuit carrier S forms an electrical insulation between the semiconductor components C1, C2 and the base plate P and additionally has a good thermal conductivity in order to dissipate the heat from the semiconductor components C1, C2 to the base plate P. In this case, the circuit carrier S may have a ceramic layer CC, wherein aluminum nitride (AN), aluminum oxide (Al2O3), beryllium oxide (BeO), silicon carbide (SiC) or silicon nitride (SiN) are preferred materials. Owing to the high thermal conductivity and thermal coefficients of expansion, preference is given to using ceramic circuit carriers S, so-called DCB substrates, which consist of a ceramic insulator CC such as aluminum oxide or aluminum nitride, on both sides of which in each case a thin layer of pure copper, specifically a first conductor layer CUI, is applied to a top side of the ceramic layer CC and a second conductor layer CU2 is applied to a bottom side of the ceramic layer CC, as illustrated in FIG. 7. The circuit carrier S is connected to the base plate P via a solder layer V.

On its top side facing the semiconductor components C1, C2, the circuit carrier S has a first conductor layer CUI which is structured into multiple conductor tracks F1 and F2 according to circuit requirements: in the present example, the conductor tracks comprise, in addition to a first conductor track F1, a second conductor track having the input contact L1. The conductor tracks F1 and F2 were formed by a structuring of the first conductor layer CU1, which was arranged on the top side of the ceramic layer CC.

The electronic semiconductor components C1, C2 are mechanically and electrically connected to the conductor tracks F1, F2; these electrical connections may be produced by solder layers V. Instead of the solder layers V between the semiconductor components C1, C2 and the circuit carrier S, another cohesive connection or securing which ensures good electrical and thermal contact is also possible, for example via an intermediate layer in the form of a metal plate. Electrical connections between the conductor tracks F1, F2 and the semiconductor components C1, C2 and between the semiconductor components C1, C2 are produced by bonding wires D. Instead of using bonding wires, these electrical connections may also be made using other connecting elements.

The power semiconductor module 4 furthermore comprises a housing H which is closed off by the base plate P and thus forms a housing interior. Plastic housings are customary.

In addition to being made of plastic, the housing H may also be made of another dielectric, in particular a ceramic. Ceramics are inexpensive and resistant and have good thermal conductivity for electrical insulators. This thermal conductivity is important in order to dissipate the heat arising.

For mutual electrical insulation of the components of the power semiconductor module 4 and for sealing off the circuit construction from the external atmosphere, the housing H is at least partially encapsulated with a potting compound M in the direction of the base plate P. Typically, the housing volume is filled with potting compound M to such an extent that it uniformly surrounds the semiconductor components C1, C2 and the customary standard specifications are met. The terminals 51, 52 of the power semiconductor module 4 are led out of the encapsulated housing H at suitable locations via the contact surfaces L1, L2 of the circuit carrier S and solder layers V in order to provide external terminals of the power semiconductor module 4.

FIG. 8 shows a section through a power module 4 according to the invention according to a further configuration. In contrast to the construction shown in FIG. 7, in the construction of the power module 4 shown in FIG. 8, there is no base plate P, heat-conducting layer I or fastening devices B. The circuit carrier S is merely placed on the heat sink KK via a connecting layer V.

1-9. (canceled)

10. A semiconductor component, comprising:
a circuit carrier having a first conductor layer in which a first conductor track is formed;
a first thyristor chip having an anode contact and a gate contact on a top side thereof, and a cathode contact on a bottom side thereof;
said first thyristor chip being placed by way of said cathode contact on said first conductor track to form an electrical connection between said cathode contact of said first thyristor chip and said first conductor track;
a second thyristor chip having a cathode contact and a gate contact on a top side thereof, and an anode contact on a bottom side thereof;
said second thyristor chip being placed by way of said anode contact on said first conductor track to form an electrical connection between said anode contact of said second thyristor chip and said first conductor track;
at least one electrically conductive connecting element electrically connecting said anode contact of said first thyristor chip to said cathode contact of said second thyristor chip; and
wherein said first conductor track establishes an electrical connection between said cathode contact of said first thyristor chip and said anode contact of said second thyristor chip.

11. The semiconductor component according to claim 10, further comprising:
an input contact;
an output contact electrically connected to said anode contact of said second thyristor chip by way of said first conductor track; and
at least one electrically conductive connecting element electrically connecting said input contact to said anode contact of said first thyristor chip.

12. The semiconductor component according to claim 10, further comprising:
a first control contact;
a second control contact;
at least one actuation wire electrically connecting said first control contact to said gate contact of said first thyristor chip and
at least one actuation wire electrically connecting said second control contact to said gate contact of said second thyristor chip.

13. The semiconductor component according to claim 12, further comprising:
a third control contact; and
at least one auxiliary wire electrically connecting said third control contact to said cathode contact of said second thyristor chip.

14. The semiconductor component according to claim 13, further comprising a fourth control contact electrically connected with said cathode contact of said first thyristor chip by way of said first conductor track.

15. The semiconductor component according to claim 10, wherein said at least one electrically conductive connecting element is one or more elements selected from the group consisting of a bonding wire, a stamped part, and a metal piece.

16. A power semiconductor module, comprising:
a semiconductor component according to claim 10; and
a heat sink;
a housing;
a potting compound;
wherein the circuit carrier of said semiconductor component has, in addition to said first conductor layer on a top side thereof, a second conductor layer on a bottom side thereof, and a central layer electrically insulating said first and second conductor layers from one another; and
wherein said semiconductor component is arranged on said heat sink and is housed in said housing, and said housing is filled with said potting compound.

17. The power semiconductor module according to claim 16, further comprising connecting layers respectively arranged between said thyristor chips and said first conductor track of said first conductor layer and between said heat sink and said second conductor layer.

18. The power semiconductor module according to claim 16, wherein an input contact and an output contact of said semiconductor component are each electrically connected through said potting compound to a first and a second contacting device, respectively, which are arranged outside said housing.
